(19) United States
(12) Patent Application Publication
(10) Pub. No.: US 2011/0227450 A1
(43) Pub. Date: Sep. 22, 2011

(54) RESONATOR BODY, RESONATOR DEVICE, AND ELECTRONIC DEVICE

(75) Inventor: Takashi YAMAZAKI, Shiojiri-shi (JP)

(73) Assignee: SEIKO EPSON CORPORATION, Tokyo (JP)

(21) Appl. No.: 13/043,690

(22) Filed: Mar. 9, 2011

(30) Foreign Application Priority Data
Mar. 18, 2010 (JP) 2010-062059
Dec. 28, 2010 (JP) 2010-292041

(51) Int. Cl. H01L 41/04; H01L 41/107

(52) U.S. Cl. 310/318; 310/325

(57) ABSTRACT

A resonator body includes a base portion, resonating arms that are extended from the base portion, piezoelectric body elements that are arranged on the resonating arms, first electrode layers that are arranged on the resonating arms, piezoelectric body layers that are arranged on the first electrode layers and second electrode layers that are arranged on the piezoelectric body layers, and a plurality of fine holes that penetrates at least any one layer of these layers in a thickness direction is formed.

### BACKGROUND

1. Technical Field

The present invention relates to a resonator body, a resonator device that includes the resonator body, and an electronic device that includes the resonator device.

2. Related Art

As a resonator device such as a crystal oscillator, the resonator device that includes a tuning-fork type resonator body having a plurality of resonating arms has been known (for example, refer to JP-A-2009-5022).

The resonator body illustrated in JP-A-2009-5022 has a base portion, three resonating arms that are extended so as to be parallel to each other from the base portion and a piezoelectric body element that is constituted such that a lower electrode film, a piezoelectric film, and an upper electrode are formed in this order on each of the resonating arms. In the resonator body, each of the piezoelectric body elements applies a voltage between the lower electrode and the upper electrode so that the piezoelectric film is expanded or contracted and each of the resonating arms is flexuraily vibrated.

The formation range of the lower electrode film, the piezoelectric film, and the upper electrode, or the thickness of the piezoelectric film were changed so that the piezoelectric body element becomes of a desired characteristic in the related art.

In other words, if an equivalent parallel capacity C₀ or an equivalent series capacity C₁ is small, outer shapes of the lower electrode film, the piezoelectric film, and the upper electrode are small so that the formation range (area S) of the electrode film can be decreased and the thickness d of the piezoelectric film can be thickened.

However, when the thickness of the piezoelectric film is thickened, there are problems in the process that the effect of the temperature characteristic of the piezoelectric film is increased, the temperature characteristic of the resonator body becomes worse and time of the formation of the piezoelectric film is required to be long. Also, when the formation range of the lower electrode film, the piezoelectric film, and the upper electrode is small, there are problems that deviation of the distribution of the driving force of the resonating arm in the width direction is generated so that the transmittance of the driving force of the piezoelectric body element to the resonating arm cannot be performed satisfactorily. In other words, if the lower electrode film and the upper electrode are pinched together the center of the width of the vibration arm. And, the electrodes are not formed at both sides thereof and when the formation range of the lower electrode film, the piezoelectric film, and the upper electrode is small, and the driving force is not generated at one side of both sides of the resonating arm in which the electrodes are not present so that the resonating arm is flexed by the driving force that is locally generated at the center in where the electrodes are present. Thus, some procedure such as increasing a voltage for driving between electrodes is required in order to perform a flexure of a desired strength to the resonating arm so that it is not effective.

### SUMMARY

An advantage of some aspects of the invention is that it provides a resonator body, a resonator device that includes the resonator body, and an electronic device that uses the resonator body and the resonator device, which can obtain a desired vibration characteristic easily and at relatively low cost.

### APPLICATION EXAMPLE 1

According to this application example of the invention, there is provided a resonator body including: a base portion, resonating arms that are extended from the base portion and piezoelectric body elements that are arranged on the resonating arms and vibrate the resonating arms by expanding and contracting by applying an electric current, wherein the piezoelectric body elements include a first electrode layer, a second electrode layer, and a piezoelectric body layer that is positioned between the first electrode layer and the second electrode layer, and wherein a plurality of holes that penetrates at least one layer of the first electrode layer, the piezoelectric body layer, and the second electrode layer in a thickness direction is formed.

According to this configuration of the resonator body, the effective area of the first electrode layer and the second electrode layer is small without changing a formation region (driving region) of the piezoelectric body element on the resonating arm so that the vibration characteristic of the piezoelectric body element can be adjusted.

Thus, the transmittance of the driving force of the piezoelectric body element to the resonating arm is satisfactory while the equivalent parallel capacity C₀ and the equivalent series capacity (equivalent circuit constant) C₁ are decreased respectively so as to adjust to the desired value. Also, when the vibration characteristic of the piezoelectric body element is adjusted, the thickness of the piezoelectric body layer is not required to be changed so that the temperature characteristic is prevented from changing and a problem on the process according to the thick film of the piezoelectric body layer can be prevented.

The formation of a plurality of holes can be performed during the patterning of the outer contour of the layer. Thus, there is no rise in cost according to the increase of the number of processes when manufacturing.

### APPLICATION EXAMPLE 2

It is preferable that a plurality of holes is formed on at least one side of the first electrode layer and the second electrode layer.

According to this configuration, since the first electrode layer and the second electrode layer are relatively thin, the formation of the plurality of holes can be performed relatively simply and with high precision. Even though the plurality of holes is arranged at the first electrode layer, a step which is generated at the first electrode layer is extremely small so that negative influence is not exerted on the formation of the piezoelectric body layer. Also, since the second electrode layer is formed after the formation of the first electrode layer and the piezoelectric body layer, the negative influence is not exerted on the formation of the first electrode layer and the piezoelectric body layer even though the plurality of holes is arranged at the second electrode layer.

### APPLICATION EXAMPLE 3

It is preferable that a plurality of holes is formed at least on the first electrode layer.

According to this configuration, the plurality of holes is formed at the first electrode layer so that the orientation of the piezoelectric body layer can be adjusted according to the formation state.

### APPLICATION EXAMPLE 4

It is preferable that the plurality of holes is formed on both of the first electrode layer and the second electrode layer.

According to this configuration, mechanical strength of the first electrode layer and the second electrode layer can be prevented from lowering while the effective area of the first electrode layer and the second electrode layer can be small.

### APPLICATION EXAMPLE 5

It is preferable that the plurality of holes is not formed on the piezoelectric body layer.

According to this configuration, the second electrode layer can be evenly formed. The distance between the first electrode layer and the second electrode layer can be uniformly formed.

### APPLICATION EXAMPLE 6

It is preferable that the plurality, of holes is formed on the piezoelectric body layer.

According to this configuration, the effective area of the first electrode layer and the second electrode layer can be small.

### APPLICATION EXAMPLE 7

It is preferable that the plurality of holes is evenly dispersed in a surface direction of the layer.

According to this configuration, the piezoelectric body element can be relatively easily adjusted to the desired vibration characteristic.

### APPLICATION EXAMPLE 8

It is preferable that each hole is a circular shape when the layer is seen in a plan view.

According to this configuration, the piezoelectric body element can be relatively easily adjusted to the desired vibration characteristic.

### APPLICATION EXAMPLE 9

It is preferable that an average diameter of the plurality of holes is 0.01 to 100 μm.

According to this configuration, a plurality of holes can be relatively simply formed and the piezoelectric body element can be relatively simply adjusted to a desired vibration characteristic.

### APPLICATION EXAMPLE 10

It is preferable that each of the holes is a slit shape when the layer is seen in a plan view.

According to this configuration, the piezoelectric body element can be relatively simply adjusted to a desired vibration characteristic.

### APPLICATION EXAMPLE 11

It is preferable that each hole having the slit shape is extended to an extension direction of the resonating arm or to a width direction that is orthogonal to the extension direction of the resonating arm.

According to this configuration, the piezoelectric body element can be relatively simply adjusted to a desired vibration characteristic.

### APPLICATION EXAMPLE 12

It is preferable that an average width of the plurality of holes having the slit shape is 0.01 to 100 μm.

According to this configuration, a plurality of holes can be relatively simply formed and the piezoelectric body element can be relatively simply adjusted to a desired vibration characteristic.

### APPLICATION EXAMPLE 13

It is preferable that a ratio of the area in which the plurality of holes takes a share with respect to the entire layer is 0.1 to 0.8 when the layer is seen in a plan view.

According to this configuration, mechanical strength of the piezoelectric body element can be prevented from lowering while the piezoelectric body element can be adjusted to the desired vibration characteristic.

### APPLICATION EXAMPLE 14

According to this application example of the invention, there is provided a resonator device including: the above-described resonator body and a package that accommodates the resonator body.

According to this configuration, the resonator device of this application example of the invention can obtain the desired vibration characteristic easily with relatively low cost.

### APPLICATION EXAMPLE 15

According to this application example of the invention, there is provided a resonator device including: the above-described resonator body, a driving circuit portion that is electrically connected to the resonator body, and a package that accommodates the resonator body and the driving circuit portion.

According to this configuration, the resonator device includes the driving circuit portion that is electrically connected to the resonator body so that the desired vibration characteristic can be obtained easily with relatively low cost; and a compact form thereof can be realized.

### APPLICATION EXAMPLE 16

According to this application example of the invention, there is provided an electronic device including: the above-described resonator device.

According to this configuration, the desired vibration characteristic can be obtained with easily relatively low cost.

### BRIEF DESCRIPTION OF THE DRAWINGS

The invention will be described with reference to the accompanying drawings, wherein like numbers reference like elements.

FIG. 1 is a cross section view illustrating a resonator device of a first embodiment according to the invention.

FIG. 2 is a top plan view illustrating a resonator body included in the resonator device shown in FIG. 1.

FIG. 3 is a cross section view taken along line A-A in FIG. 2.

FIG. 4 is a bottom plan view of the resonator body shown in FIG. 2.

FIG. 5 is a drawing illustrating the resonator body shown in FIG. 4, in which each of the second electrode layers that is included in the resonator body is not shown.

FIG. 6 is a drawing illustrating the resonator body shown in FIG. 4, in which each of the second electrode layers and each of piezoelectric body layers that are included in the resonator body are not shown.

FIG. 7 is a perspective view illustrating an operation of the resonator body shown in FIG. 2.

FIG. 8 is an equivalent circuit diagram of the resonator body shown in FIG. 2.

FIG. 9 is a bottom plan view illustrating a resonator body included in the resonator device of a second embodiment according to the invention.

FIG. 10 is a drawing illustrating the resonator body shown in FIG. 9, in which each of the second electrode layers and each of piezoelectric body layers that are included in the resonator body are not shown.

FIG. 11 is a bottom plan view illustrating a resonator body included in a resonator device of a third embodiment according to the invention.

FIG. 12 is a drawing illustrating the resonator body shown in FIG. 11, in which each of the second electrode layers that is included in the resonator body is not shown.

FIG. 13 is a cross section view illustrating a piezoelectric oscillator as a resonator device of a fourth embodiment according to the invention.

FIG. 14 is a perspective view schematically illustrating a cellular phone as an example of the electronic device according to the invention.

FIG. 15 is a circuit block diagram illustrating a circuit constitution of the cellular phone as an example of the electronic device according to the invention.

FIG. 16 is a perspective view schematically illustrating a personal computer as an example of the electronic device according to the invention.

### DESCRIPTION OF EXEMPLARY EMBODIMENTS

Hereinafter, a resonator body and a resonator device according to the invention will be described based on embodiments illustrated in the attached drawings in detail.

### First Embodiment

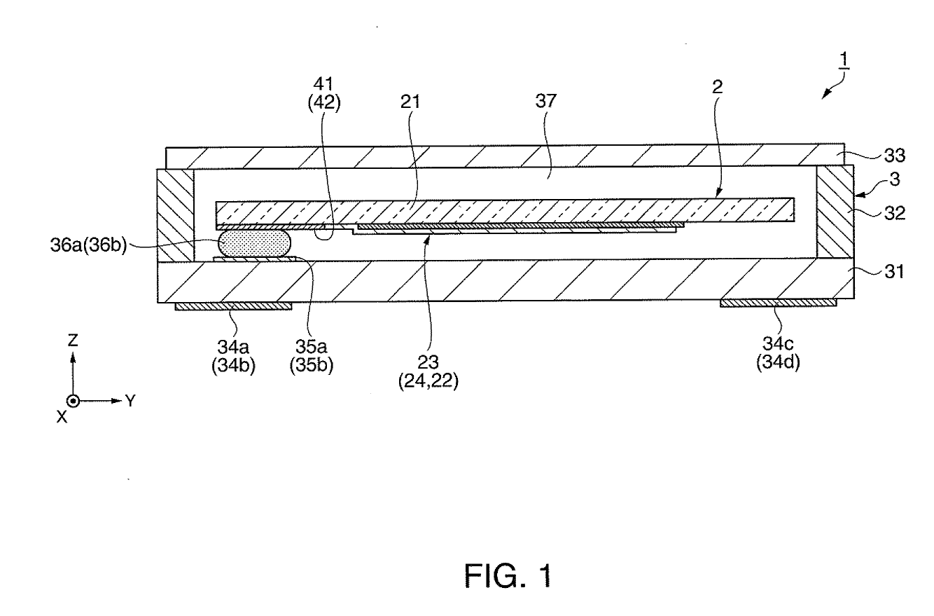

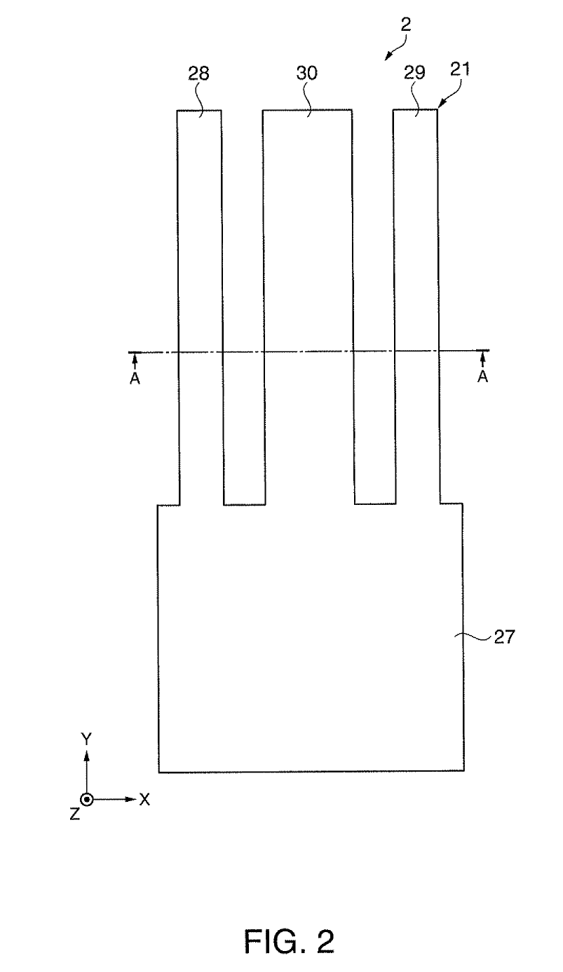

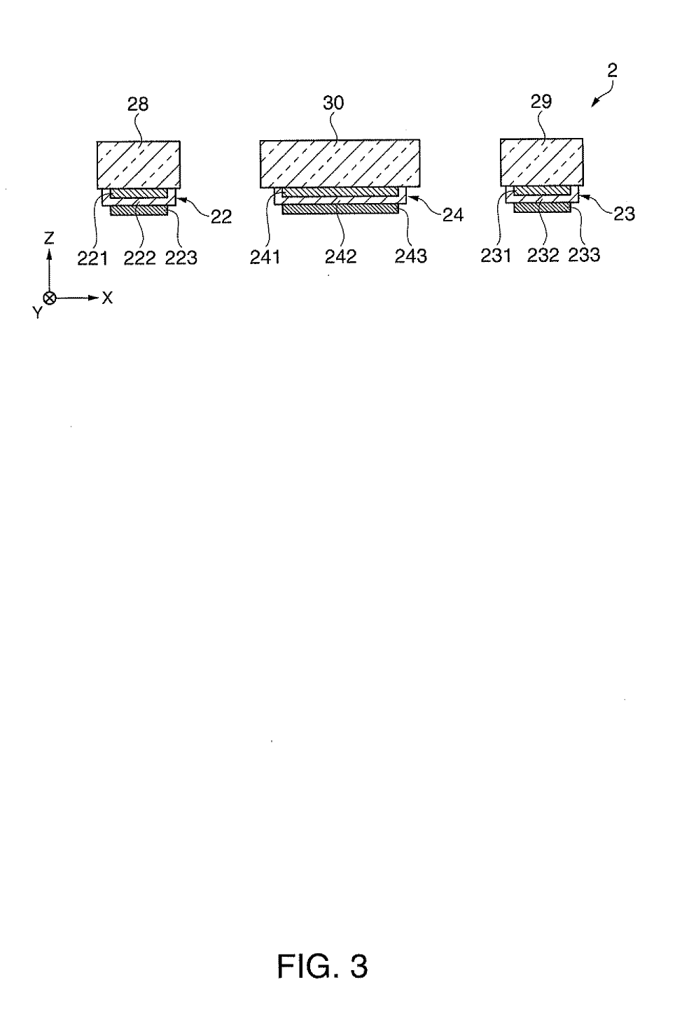

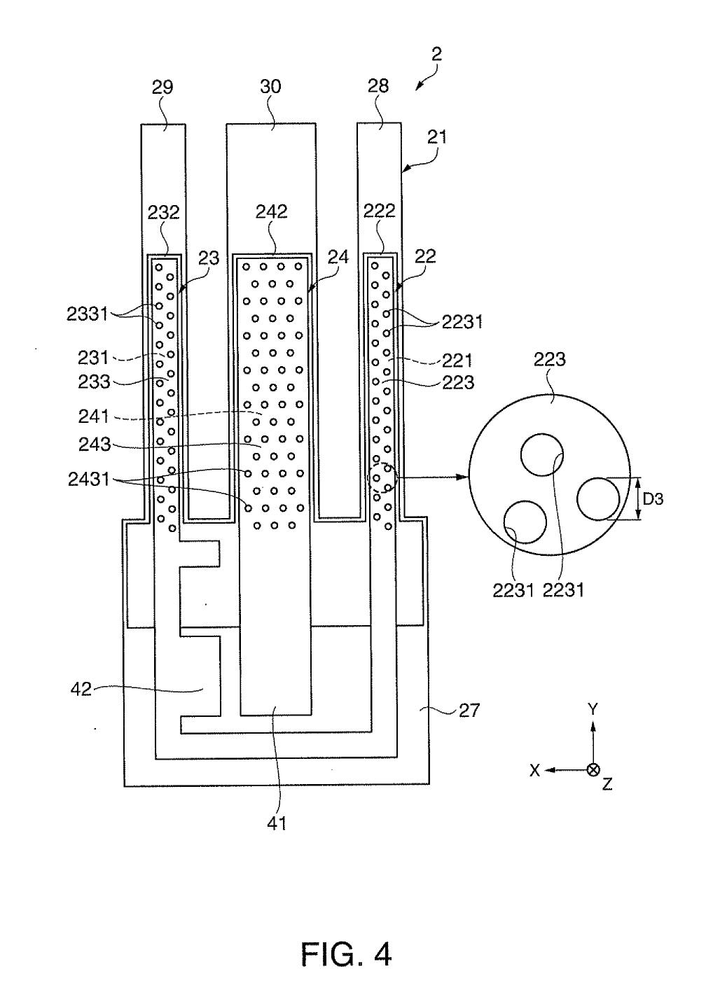

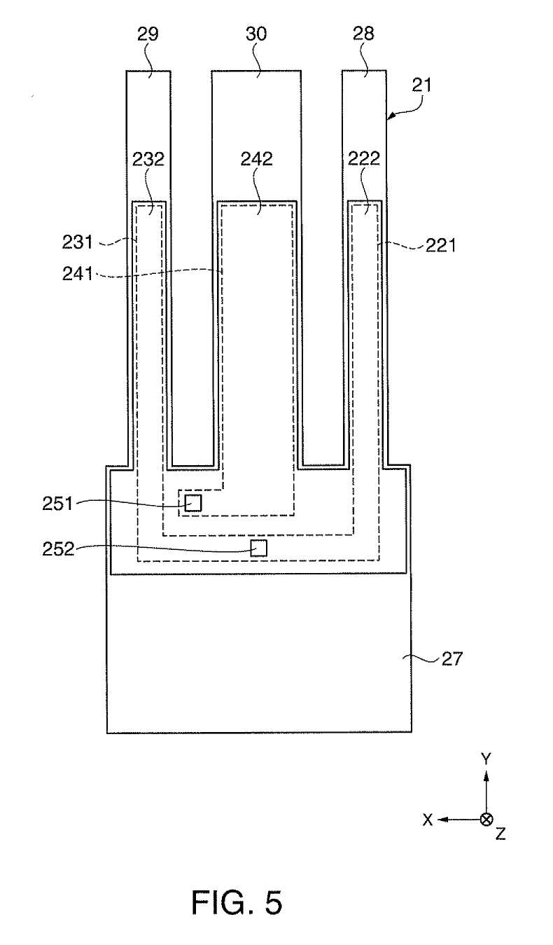

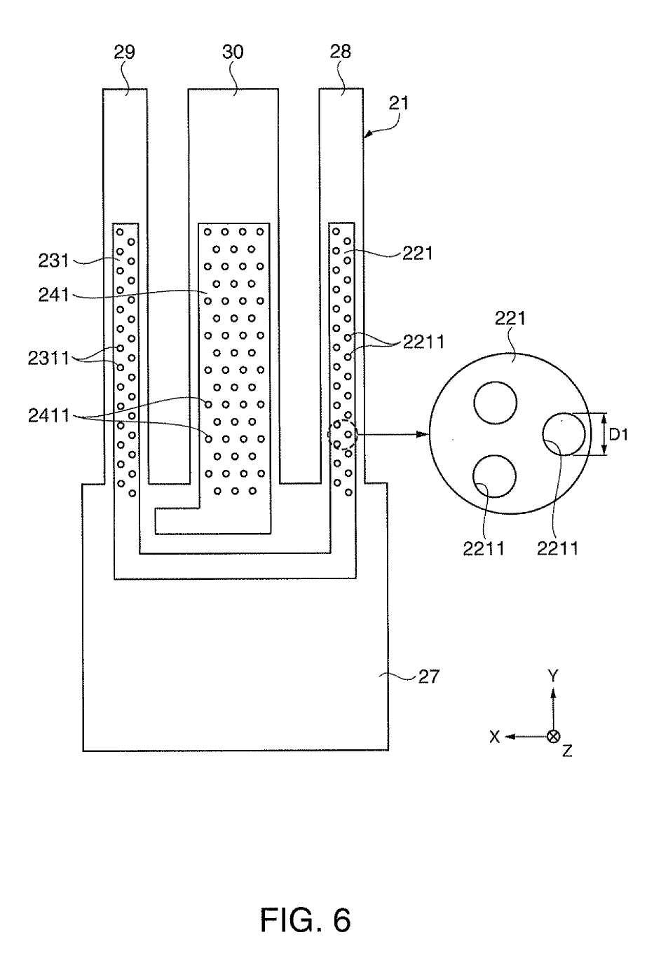

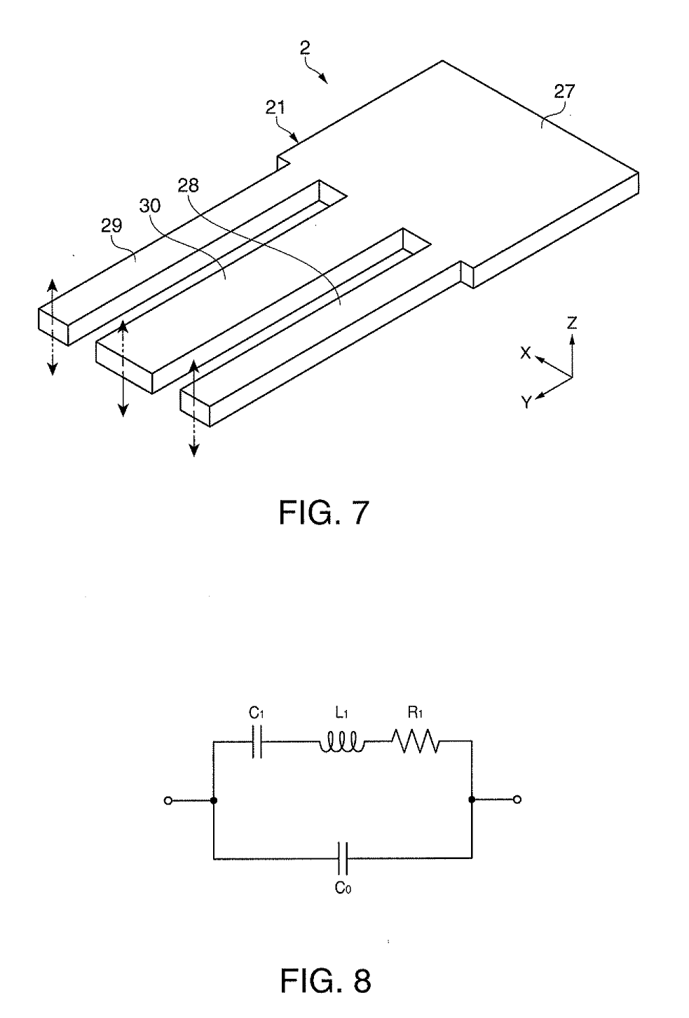

FIG. 1 is a cross section view illustrating a resonator device of a first embodiment according to the invention, FIG. 2 is a top plan view illustrating a resonator body included in the resonator device shown in FIG. 1, FIG. 3 is a cross section view taken along line A-A in FIG. 2, FIG. 4 is a bottom plan view of the resonator body shown in FIG. 2, FIG. 5 is a drawing illustrating the resonator body shown in FIG. 4 in which each of the second electrode layers that is included in the resonator body is not shown, FIG. 6 is a drawing illustrating the resonator body shown in FIG. 4 in which each of the second electrode layers and each of piezoelectric body layers that are included in the resonator body are not shown, FIG. 7 is a perspective view illustrating an operation of the resonator body shown in FIG. 2, and FIG. 8 is an equivalent circuit diagram of the resonator body shown in FIG. 2. In each of the drawings, for the sake of convenience of description, the X-axis, the Y-axis and the Z-axis are illustrated orthogonal to each other as three axes. Hereinafter, a direction (the first direction) that is parallel to the X-axis is referred to as “X-axis direction”, a direction (the second direction) that is parallel to the Y-axis is referred to as “Y-axis direction” and a direction (the third direction) that is parallel to the Z-axis is referred to as “Z-axis direction”. Also, in the description below, for the sake of convenience of description, an upper side in FIG. 1 is referred to as “upper”, a lower side is referred to as “lower”, a right side is referred to as “right” and a left side is referred to as “left”.

A resonator device 1 illustrated in FIG. 1 has a resonator body 2 and a package 3 in which the resonator body 2 is accommodated.

Hereinafter, each of the portions that constitute the resonator device 1 is described in detail in regular sequence.

### Resonator Body

First of all, description will be given regarding the resonator body 2.

The resonator body 2 is a tuning-fork type resonator body having three legs as illustrated in FIG. 2. The resonator body 2 has a resonator substrate 21, piezoelectric body elements 22, 23, and 24 that are arranged on the resonator substrate 21, and connection electrodes 41 and 42.

The resonator substrate 21 has a base portion 27 and three resonating arms 28, 29, and 30.

As the constituent material of the resonator substrate 21, it is not specifically limited to any materials if the materials exert a desired vibration characteristic; and various types of piezoelectric material and various types of non-piezoelectric material can be used.

For example, crystal, lithium tantalate, lithium niobate, lithium borate, barium titanate, or the like are used as examples of the piezoelectric material. Specifically, crystal is preferable as the piezoelectric material that constitutes the resonator substrate 21. When the resonator substrate 21 is constituted of crystal, the vibration characteristic of the resonator substrate 21 can be excellent in the frequency temperature characteristic. Also, the resonator substrate 21 can be formed with high precision dimension by etching.

As non-piezoelectric materials, for example, silicon, quartz, or the like can be used. Specifically, as the non-piezoelectric materials constitute the resonator substrate 21, silicon is preferable. When the resonator substrate 21 is constituted of silicon, the vibration characteristic of the resonator substrate 21 may be excellent with relatively low cost and easily integrated to other circuit elements such that an integrated circuit is formed at the base portion 27 or the like. Also, the resonator substrate 21 can be formed with high precision dimension by etching.

In such a resonator substrate 21, the base portion has a tetragonal shape seen in the plan view constituted of a pair of sides that is parallel to the X-axis direction and a pair of sides that is parallel to the Y-axis direction. The shape of the base portion 27 seen in plan view is not limited to the above description.

Three resonating arms 28, 29, and 30 are connected to one side of the base portion 27 that is parallel to the X-axis direction.

The resonating arms 28 and 29 are connected to both end portions of the base portion 27 in the X-axis direction and the resonating arm 30 is connected to a center portion of the base portion 27 in the X-axis direction.

Three resonating arms 28, 29, and 30 are extended from the base portion 27 respectively so as to be parallel to each other. In other words, three resonating arms 28, 29, and 30 are extended in the Y-axis direction (arrow direction of Y-axis) respectively and arranged in the X-axis direction from the base portion 27.

The resonating arms 28, 29, and 30 have a longitudinal shape respectively, an end portion (a base end portion) of the base portion 27 is a fixed end and an end portion (a front end portion) that is opposite to the base portion 27 is a free end.

The resonating arms 28 and 29 are formed to having the same width to each other and the resonating arm 30 is formed to having a width that is two times that of the resonating arms 28 and 29. Accordingly, when the resonating arms 28 and 29 are flexuraily vibrated in the Z-axis direction and the resonating arm 30 is flexuraily vibrated in the Z-axis direction opposite (reverse phase) to the resonating arms 28 and 29, loss of the vibration can be reduced.

Each of the resonating arms 28, 29, and 30 has a constant width through an overall area in the longitudinal direction. If necessary, a mass portion (a hammer head) of which the cross section area is larger than that of the base end portion may be arranged, at each of the front end portions of the resonating arms 28, 29, and 30. In this case, the resonator body 2 can be a more compact size and the frequency of the flexural vibration of the resonating arms 28, 29, and 30 can be further lowered.

As shown in FIG. 3, a piezoelectric body element 22 is arranged on the resonating arm 28, a piezoelectric body element 23 is arranged on the resonating arm 29, and a piezoelectric body element 24 is arranged on the resonating arm 30.

The piezoelectric body element 22 has a function that performs a flexural vibration of the resonating arm in the Z-axis direction by expanding and contracting according to applying the electric current. The piezoelectric body element 23 has a function that performs a flexural vibration of the resonating arm 29 in the Z-axis direction by expanding and contracting according applying the electric current. The piezoelectric body element 24 has a function that performs a flexural vibration of the resonating arm 30 in the Z-axis direction by expanding and contracting by applying the electric current.

As described above, as shown in FIG. 3, the piezoelectric body element 22 is constituted of a first electrode layer 221, a piezoelectric body layer (piezoelectric film) 222 and a second electrode layer 223 which are laminated on the resonating arm 28 in this order.

As shown in FIG. 4, a plurality of fine holes 2231 that penetrates the second electrode layer 223 in the thickness direction is formed. Also, as shown in FIG. 6, a plurality of fine holes 2211 that penetrates the first electrode layer 221 in the thickness direction is formed. Such a plurality of holes is formed at the first electrode layer 221 and the second electrode layer 223 respectively so that the vibration characteristic of the piezoelectric body element 22 is adjusted. The adjustment of the vibration characteristic of the piezoelectric body element 22 will be described below. A plurality of holes may be formed at either one of the first electrode layer 221 and the second electrode layer 223, however a concavo-convex form is less present in a case where a plurality of holes 2231 is formed only at the second electrode layer 223 than in a case where holes are formed at the first electrode layer 221 even though it is a small amount. Thus, the piezoelectric body layer 222 and the first electrode layer 221 can be formed flat so that the strength of the electric field between electrode layers can easily be exactly constant.

In the piezoelectric body element 22, since the piezoelectric body layer 222 is arranged between the first electrode layer 221 and the second electrode layer 223, when a voltage is applied between the first electrode layer 221 and the second electrode layer 223, the electric field is generated in the piezoelectric body layer 222 in the Z-axis direction. The piezoelectric body layer 222 is expanded or contracted in the Y-axis direction and the resonating arm 28 is flexuraily vibrated in the Z-axis direction by the electric field.

Similar to the above description, the piezoelectric body element 23 is constituted of a first electrode layer 231, a piezoelectric body layer (piezoelectric film) 232 and a second electrode layer 233 which are laminated on the resonating arm 29 in this order. Also, the piezoelectric body element 24 is constituted of a first electrode layer 241, a piezoelectric body layer (piezoelectric film) 242 and a second electrode layer 243 which are laminated on the resonating arm 30 in this order.

As shown in FIG. 4, a plurality of fine holes 2331 that penetrates the second electrode layer 233 in the thickness direction is formed. Also, as shown in FIG. 6, a plurality of fine holes 2311 that penetrates the first electrode layer 231 in the thickness direction is formed. Such a plurality of holes is formed at the first electrode layer 231 and the second electrode layer 233 respectively so that the vibration characteristic of the piezoelectric body element 23 is adjusted. A plurality of holes may be formed at any one of the first electrode layer 231 and the second electrode layer 233, however a concavo-convex form is less present in a case where a plurality of holes 2331 is formed only at the second electrode layer 233 than in a case where holes are formed at the first electrode layer 231 even though it is a small amount. Thus, the piezoelectric body layer 232 and the first electrode layer 231 can be formed flat so that the strength of the electric field between electrode layers can easily be exactly constant.

As shown in FIG. 4, a plurality of fine holes 2431 that penetrates the second electrode layer 243 in the thickness direction is formed. Also, as shown in FIG. 6, a plurality of fine holes 2411 that penetrates the first electrode layer 241 in the thickness direction is formed. Such a plurality of holes is formed at the first electrode layer 241 and the second electrode layer 243 respectively so that the vibration characteristic of the piezoelectric body element 24 is adjusted. A plurality of holes may be formed at any one of the first electrode layer 241 and the second electrode layer 243, however a concavo-convex form is less present in a case where a plurality of holes 2431 is formed only at the second electrode layer 243 than in a case where holes are formed at the first electrode layer 241 even though it is a small amount. Thus, the piezoelectric body layer 242 and the first electrode layer 241 can be formed flat so that the strength of the electric field between electrode layers can easily be exactly constant.

In the piezoelectric body element 23 as described above, when a voltage is applied between the first electrode layer 231 and the second electrode layer 233, the piezoelectric body layer 232 is expanded or contracted in the Y-axis direction and the resonating arm 29 is flexuraily vibrated in the Z-axis direction. Also, when, a voltage is applied between the first electrode layer 241 and the second electrode layer 243, the piezoelectric body layer 242 is expanded or contracted in the Y-axis direction and the resonating arm 30 is flexuraily vibrated in the Z-axis direction.

As shown in FIGS. 4 to 6, the above described first electrode layer 221 and 231 and the second electrode layer 243 are electrically connected to the connection electrode 41 arranged on the lower surface of the base portion 27. The first electrode layer 241 and the second electrode layers 223 and 233 are electrically connected to the connection electrode 42 arranged on the lower surface of the base portion 27. Thus, the first electrode layer 241 is electrically connected to the connection electrode 41 through the conductive portion (conductive post) 251 shown in FIG. 5. Also, the first electrode layers 221 and 231 are electrically connected to the connection electrode 42 through the conductive portion (conductive post) 252 shown in FIG. 5.

The first electrode layers 221, 231, and 241, the second electrode layers 223, 233, and 243, the connection electrodes 41 and 42; and the conductive portions 251 and 252 can be formed by a metal material that is excellent in conductivity such as gold, gold alloy, aluminum, aluminum alloy, silver, silver alloy, chromium, or chromium alloy respectively.

As a forming method of these electrodes, a physical film forming method such as a sputtering method and a vacuum vapor deposition method, a chemical vapor deposition method such as CVD, and various coating methods such as an ink jet method can be used. When these electrodes are formed, it is preferable that a photolithography method is used.

The same film forming process can form the first electrode layers 221, 231, and 241 and the same film forming process can form the second electrode layers 223, 233, and 243.

As the constituent material (piezoelectric material) of the piezoelectric body layers 222, 232, and 242, for example, crystal, lithium tantalate, lithium niobate, lithium borate, barium titanate, or the like, besides ZnO (Zinc Oxide), AlN (Aluminum Nitride), and PZT (Lead zirconate titanate) may be used.

As a forming method of the piezoelectric body layer, a physical film forming method such as a sputtering method and a vacuum vapor deposition method, a chemical vapor deposition method such as CVD (Chemical Vapor Deposition), and various coating methods such as an ink jet method can be used.

Also, the piezoelectric body layers 222, 232, and 242 can be formed by the same film forming process.

In the resonator body 2 as described above, when a voltage is applied between the connection electrode 41 and the connection electrode 42, the first electrode layers 221 and 231 and the second electrode layer 243; and the first electrode layer 241 and the second electrode layers 223 and 233 become reverse polarity so that the voltage of the Z-axis direction is applied to the piezoelectric body layers 222, 232, and 242 respectively. Thus, each of the resonating arms 28, 29, and 30 can performs flexural vibration with a constant frequency (a resonance frequency) due to a reverse voltage effect of the piezoelectric material. At this time, as shown in FIG. 7, the resonating arms 28 and 29 perform the flexural vibration in the same direction to each other and the resonating arm 30 performs the flexural vibration in the opposite direction to the resonating arms 28 and 29. As described above, adjacent two resonating arms perform the flexural vibration in the opposite direction to each other so that the transmittance of the vibration to the base portion 27 can be decreased.

When each of the resonating arms 28, 29, and 30 is flexuraily vibrated, the voltage having a constant frequency is generated by the piezoelectric effect of the piezoelectric material between the connection electrodes 41 and 42. The resonator body 2 can generate an electric signal that is vibrated in the resonance frequency using these properties.

The resonator body 2 as described above can be illustrated in the equivalent circuit as shown in FIG. 8. In FIG. 8, C₀ is an equivalent parallel capacity, R₁ is an equivalent series resistance, L₁ is an equivalent series inductance and C₁ is an equivalent series capacity. The equivalent parallel capacity C₀, the equivalent series resistance R₁, the equivalent series inductance L₁, and the equivalent series capacity C₁ are determined by length and width of the resonating arms 28, 29, and 30, effective area of the first electrode layers 221, 231, and 241 and the second electrode layers 223, 233, and 243; and permittivity and thickness of the piezoelectric body layers 222, 232, and 242.

When an effective area of the first electrode layers 221, 231, and 241 and the second electrode layers 223, 233, and 243 is S; and thickness of the piezoelectric body layers 222, 232, and 242 is d, a relation of C₀∝S/d is completed regarding the equivalent parallel capacity C₀ of the resonator body 2.

Here, an effective area of the first electrode layers 221, 231, and 241 and the second electrode layers 223, 233, and 243 is an overlapped area in a state that the piezoelectric body layers 222, 232, and 242 are interposed between the first electrode layers 221, 231, and 241 and the second electrode layers 223, 233, and 243.

In the embodiment, description has been given regarding the case when the polarization direction or the crystal axis direction of the piezoelectric material of the piezoelectric body layers 222, 232, and 242 is the same direction to each other, however the invention is not limited to the description and for example, the polarization direction or the crystal axis direction of the piezoelectric body layer 242 is opposite to that of the piezoelectric body layers 222 and 232 and the voltage may be applied so that the first electrode layers 221, 231, and 241 among themselves (the second electrode layers 223, 233, and 243 among themselves) become the same polarization.

Description will be given regarding the adjustment of vibration characteristic of the piezoelectric body element 22. The adjustment of vibration characteristic of the piezoelectric body elements 23 and 24 is similar to the adjustment of vibration characteristic of the piezoelectric body elements 22, thus the description thereof is omitted.

As described above, a plurality of fine holes 2211 that penetrates the first electrode layer 221 in the thickness direction is formed and a plurality of fine holes 2231 that penetrates the second electrode layer 223 in the thickness direction is formed at the piezoelectric body element 22.

Accordingly, the effective area of the first electrode layer 221 and the second electrode layer 223 is small so that the vibration characteristic of the piezoelectric body element 22 can be adjusted without changing a formation region (driving region) of the piezoelectric body element 22 on the resonating arm 28 (or for example, the width of the formation region is widely formed according to the width of the resonating arm). In other words, the density of the electric field (the electric field that is applied to the piezoelectric body layer 222) that is generated between the first electrode layer 221 and the second electrode layer 223 is small so that the vibration characteristic of the piezoelectric body element 22 can be adjusted without changing the outer contours (the shape and area of the contour) of the first electrode layer 221, the piezoelectric body layer 222 and the second electrode layer 223 respectively.

Thus, the transmittance of the driving force of the piezoelectric body element 22 with respect to the resonating arm 28 is satisfactory while the equivalent parallel capacity C₀ and the equivalent series capacity C₁ are small respectively so that the adjustment can be performed to a desired value. When the vibration characteristic of the piezoelectric body element 22 is adjusted, the thickness of the piezoelectric body layer 222 is not required to be changed so that the temperature characteristic is prevented from changing and a problem on the process according to the thick film of the piezoelectric body layer 222 can be prevented.

The formation (patterning) of a plurality of holes 2211 and 2231 can be performed during the patterning of the outer contour of the first electrode layer 221 or the second electrode layer 223. Thus, there is no rise in cost according to the increase of the number of processes when manufacturing.

Thus, the resonator body 2 can obtain a desired vibration characteristic simply and at relatively low cost.

If a plurality of holes is formed only any one of the first electrode layer 221 or the second electrode layer 223, since the number or area of a plurality of holes per one electrode layer becomes large, the continuity failure such as electric short circuiting can be easily generated in the electrode layer.

In the embodiment, the above described plurality of holes is formed on both of the first electrode layer 221 and the second electrode layer 223, so that the number or area of a plurality of holes per one electrode layer can be decreased compared to the case where a plurality of holes is formed only any one of the first electrode layer 221 or the second electrode layer 223. Thus, the generation of the continuity failure of the first electrode layer 221 and the second electrode layer 223 can be prevented and simultaneously the effective area of the first electrode layer 221 and the second electrode layer 223 can be reduced. The holes 2211 and the holes 2231 may not be overlapped to each other as possible as seen in the plan view so that the effect becomes further remarkable.

Since the first electrode layer 221 and the second electrode layer 223 are relatively thin, the formation of a plurality of the holes 2211 and 2231 can be performed relatively simply and in high precision. Even though a plurality of the holes 2211 is arranged at the first electrode layer 221, a step which is generated by presence or absence of the holes 2211 at the first electrode layer 221 is extremely small so that negative influence is not exerted on the formation of the piezoelectric body layer 222. Also, since the second electrode layer 223 is formed after the formation of the first electrode layer 221 and the piezoelectric body layer 222, the negative influence is not exerted on the formation of the first electrode layer 221 and the piezoelectric body layer 222 even though the plurality of holes 2231 is arranged at the second electrode layer 223.

A plurality of holes 2211 is formed at the first electrode layer 221 so that the orientation of the piezoelectric body layer 222 can be adjusted according to the formation state. The vibration characteristic of the piezoelectric body element 22 can be adjusted even by the adjustment of the orientation of the piezoelectric body layer 222.

In the embodiment, a plurality of holes such as 2211 and 2231 is not formed at the piezoelectric body layer 222. In other words, the piezoelectric body layer 222 is constituted such that the inner side of the contour thereof is not patterned but densely layered. Thus, the surface of the piezoelectric body layer 222 can be flat. As a result, the second electrode layer 223 can be evenly formed. The distance between the first electrode layer 221 and the second electrode layer 223 can be uniformly formed.

A plurality of holes 2211 is evenly dispersed in the surface direction of the first electrode layer 221 and a plurality of holes 2231 is evenly dispersed in the surface direction of the second electrode layer 223. In other words, a plurality of holes 2211 is formed so as to penetrate the first electrode layer 221 in the thickness direction and evenly dispersed in the surface direction that is substantially orthogonal to the thickness direction. A plurality of holes 2231 is formed so as to penetrate the second electrode layer 223 in the thickness direction and evenly dispersed in the surface direction that is substantially orthogonal to the thickness direction. Thus, the piezoelectric body element 22 can be relatively simply adjusted to the desired vibration characteristic. A plurality of holes 2211 and 2231 may be formed within a region that exerts the driving of the resonating arm 28 out of the electrode layers, may be partially (for example, a portion of the Y-axis direction) unevenly distributed in the surface direction of the electrode layer and may be dispersed. A plurality of holes 2211 and 2231 may be dispersed for example, in a regular shape such as a matrix shape and may be dispersed in random.

Each of the holes 2211 and 2231 has a circular shape seeing the first electrode layer 221 or the second electrode layer 223 in the plan view. Here, the circular shape includes a substantially circular shape that is near the circular shape. The holes 2211 and 2231 having the shape seen in plan view can be simply formed in a high precision dimension and a negative effect that is exerted on the piezoelectric body element 22 can be reduced. Thus, the piezoelectric body element 22 can be relatively simply adjusted to the desired vibration characteristic. Specifically, each of the holes 2211 having the shape seen in plan view and each of the holes 2231 having the shape seen in plan view is the same to each other so that the adjustment of vibration characteristic of the piezoelectric body element 22 can be easily performed.

Each shape of the holes 2211 and 2231 seen in plan view is not limited to the circular shape and for example, may be an oval shape or a polygon such as a triangle or a quadrangle.

Average diameters D1 and D3 of the plurality of holes 2211 and 2231 are preferably 0.01 to 100 μm and more preferably 0.1 to 10 μm respectively. Thus, the formation of a plurality of the holes 2211 and 2231 is relatively easily performed and the piezoelectric body element 22 can be adjusted to the desired vibration characteristic.

Meanwhile, if the average diameters D1 and D3 are less than the lower limit, the formation of the plurality of holes 2211 and 2231 may be difficult by constituent material and thickness of the first electrode layers 221 and 223. Meanwhile, if the average diameters D1 and D3 are more than the upper limit, the share of the area of the holes 2211 and 2231 is difficult to increase. The driving force that the piezoelectric body element 22 generates may be unevenness and negative influence may be exerted to the vibration characteristic of the resonating arm 28 by the range or the position in which the piezoelectric body element 22 is formed.

The average diameter D1 of a plurality of holes 2211 and the average diameter D3 of a plurality of holes 2231 may be different, however it is preferable that they are substantially same. Accordingly, the vibration characteristic of the piezoelectric body element 22 is easily adjusted.

When the first electrode layer 221 is seen in the plan view, the ratio (the share of the area) of the area in which the plurality of holes 2211 takes a share with respect to the entire first electrode layer 221 and when the second electrode layer 223 is seen in the plan view, the ratio of the area in which the plurality of holes 2231 takes a share with respect to the entire second electrode layer 223 are determined according to the obtained vibration characteristic of the piezoelectric body element 22. The ratio is preferably 0.1 to 0.8 and more preferably 0.2 to 0.7. In other words, when the first electrode layer 221 is seen in the plan view, the ratio of the area in which the electrodes take a share within the region that is surrounded by the contour of the first electrode layer 221 and when the second electrode layer 223 is seen in the plan view, the ratio of the area in which the electrodes take a share within the region that is surrounded by the contour of the second electrode layer 223 are preferably 0.2 to 0.9 and more preferably 0.3 to 0.8 respectively. Thus, the continuity failure of the piezoelectric body element 22 can be prevented and the piezoelectric body element 22 can be adjusted to the desired vibration characteristic.

Meanwhile, if the ratio of the area of a plurality of holes 2211 and 2231 is less than the lower limit, there is a case that the driving force that the piezoelectric body element 22 generates may be unevenness by the shape or the size of the holes 2211 and 2231. Meanwhile, if the ratio of the area of a plurality of holes 2211 and 2231 is more than the upper limit, the first electrode layer 221 or the second electrode layer 223 may be weakened by the shape or the size of the holes 2211 and 2231 so that the durability of the piezoelectric body element 22 tends to decrease.

### Package

Next, description will be given regarding the package 3 that accommodates and fixes the resonator body 2.

As shown in FIG. 1, the package 3 has a plate shaped base substrate 31, a frame shaped frame member 32 and a plate shaped lid member 33. The base substrate 31, the frame member 32, and the lid member 33 are laminated in this order from the lower side to the upper side. The base substrate 31 and the frame member 32 are formed from a ceramic material as described below, wired integrally to each other and then connected together. The frame member 32 and the lid member 33 are connected to each other by an adhesive or a brazing filler metal. Thus, the package 3 accommodates the resonator body 2 in an inner space 37 partitioned by the base substrate 31, the frame member 32, and the lid member 33. Electronic device or the like that drive the resonator body 2 can also be accommodated within the package 3 besides the resonator body 2.

As the constituent material of the base substrate 31, it is preferable to have insulation property (non-conductivity), for example, various types of glass, various types of ceramic material such as oxide ceramics, nitride ceramics, or carbide ceramics, and various types of resin materials such as polyimide can be used.

As the constituent material of the frame member 32 and the lid member 33, for example, the same constituent material as the base substrate 31, various types of metal materials such as Al or Cu, various types of glass, or the like can be used. Specifically, as the constituent material of the lid member 33, if a material that has light transmittance such as a glass material is used, when a metal coating portion (not shown) is formed at the resonator body 2 beforehand, even though the resonator body 2 is accommodated after in the package 3, irradiates the laser to the metal coating portion through the lid member 33, the metal coating portion is removed, and then the mass of the resonator body 2 is decreased (by mass decreasing method) so that the frequency adjustment of the resonator body 2 can be performed.

A pair of mount electrodes 35a and 35b is formed on the upper surface of the base substrate 31 so as to be exposed to the inner space 37. Conductive adhesives 36a and 36b such as epoxy, polyimide, and silicon including conductive particles are coated (covered) on the mount electrodes 35a and 35b respectively. The resonator body is loaded on the conductive adhesives 36a and 36b. Thus, the resonator body 2 (the base portion 27) is reliably fixed to the mount electrodes 35a and 35b (the base substrate 31).

The fixing is performed with the resonator body 2 being loaded on the conductive adhesives 36a and 36b so that the conductive adhesive 36a is contacted to the connection electrode 42 of the resonator body 2 and the conductive adhesive 36b is contacted to the connection electrode 41 of the resonator body 2. Thus, the resonator body 2 is fixed to the base substrate 31 through the conductive adhesives 36a and 36b. The connection electrode 42 and the mount electrode 35a are electrically connected through the conductive adhesive 36a and the connection electrode 41 and the mount electrode 35b are electrically connected through the conductive adhesive 36b.

A concave portion 55 having a concave bottom surface 53 around which a wall surface is formed is arranged at the base substrate 31. The plurality of lead electrodes is formed at the concave bottom surface 53. A semiconductor element 50 is connected to a plurality of lead electrodes 51 through the metal bump 52. The semiconductor element 50 and the lead electrodes 51 may also be electrically connected through a metal wire (bonding wire) that is formed by, for example, a wire bonding technique.

The lead electrode 51 and the mount electrodes 35a and 35b are electrically connected to each other through a circuit wiring (not shown).

Four outer terminals 34a, 34b, 34c, and 34d are arranged at the lower surface of the base substrate 31.

The outer terminals 34a and 34b, out of these four outer terminals 34a to 34d are hot terminals that are electrically connected to the mount electrodes 35a and 35b through a conductive post (not shown) that is arranged at the through hole that is formed in the base substrate 31 respectively. The other two outer terminals 34c and 34d are dummy terminals for increasing the connection strength and uniformizing the distance between the package 3 and the mounting substrate respectively when the package 3 is mounted on the mounting substrate.

As described above, the mount electrodes 35a and 35b and the outer terminals 34a to 34d can be formed for example, with gold coating at the base layer of tungsten and nickel coating respectively.

The mount electrodes 35a and 35b and the connection electrodes 41 and 42 may be electrically connected through a metal wire (bonding wire) formed, for example, by a wire bonding technique. In this case, the resonator body 2 can be fixed to the base substrate 31 through an adhesive that does not have conductivity, instead of the conductive adhesives 36a and 36b. In a case where the electronic part is accommodated within the package 3, if necessary, a write-in terminal that is to perform a rewrite (adjustment) of a characteristic inspection of the electronic part or various types of information (for example, the temperature compensating information of the resonator device) within the electronic part may be formed on the lower surface of the base substrate 31.

According to the first embodiment as described above, a plurality of fine holes 2211, 2311, and 2411 that penetrates the first electrode layers 221, 231, and 241 in the thickness direction is formed and a plurality of fine holes 2231, 2331, and 2431 that penetrates the second electrode layers 223, 233 and 243 in the thickness direction is formed so that the effective area of the first electrode layers 221, 231, and 241 and the second electrode layers 223, 233, and 243 is reduced and then the vibration characteristic of the piezoelectric body elements 22, 23, and 24 can be adjusted without changing the formation region (the driving region) of the piezoelectric body elements 22, 23, and 24 on the resonating arms 28, 29, and 30.

Thus, the transmittance of the driving force of the piezoelectric body elements 22, 23, and 24 with respect to the resonating arms 28, 29, and 30 is satisfactory while the equivalent parallel capacity C₀ and the equivalent series capacity C₁ are small respectively so that the adjustment can be performed to a desired value. When the vibration characteristic of the piezoelectric body element 22, 23, and 24 is adjusted, the thickness of the piezoelectric body layer 222, 232, and 242 is not required to be changed so that the temperature characteristic is prevented from changing and a problem on the process according to be thick of the film of the piezoelectric body layer 222, 232, and 242 can be prevented.

The formation (patterning) of a plurality of holes 2211, 2311, 2411, 2231, 2331, and 2431 can be performed during the patterning of the outer contour of the first electrode layers 221, 231, and 241 or the second electrode layers 223, 233, and 243. Thus, there is no rise in cost according to the increase of the number of processes when manufacturing.

Accordingly, the resonator body 2 can obtain a desired vibration characteristic simply and at relatively low cost.

### Second Embodiment

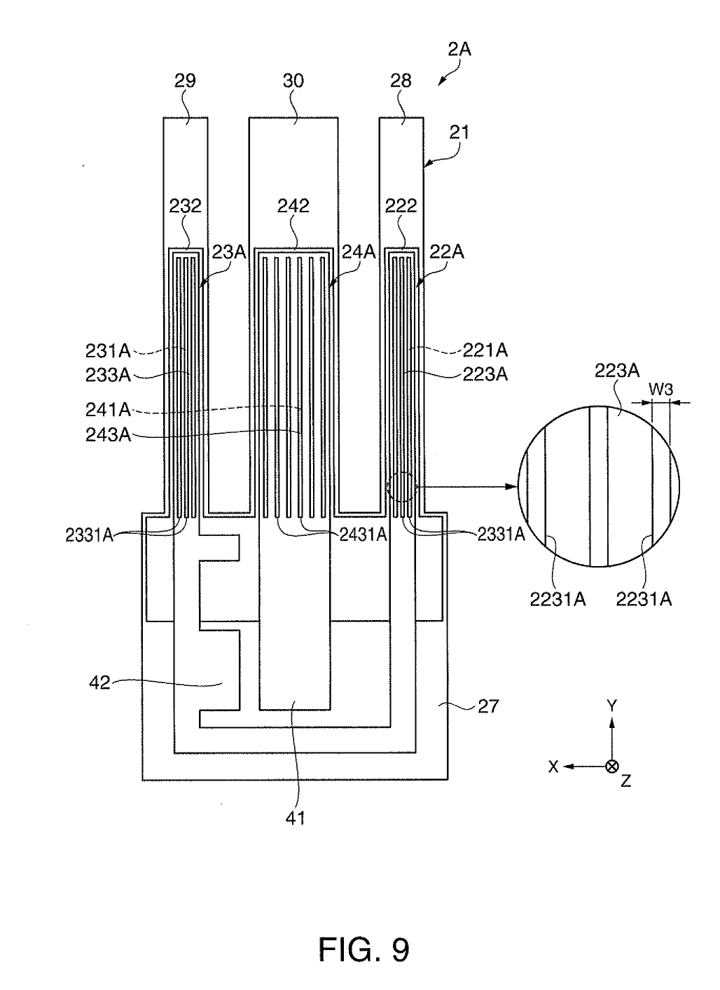

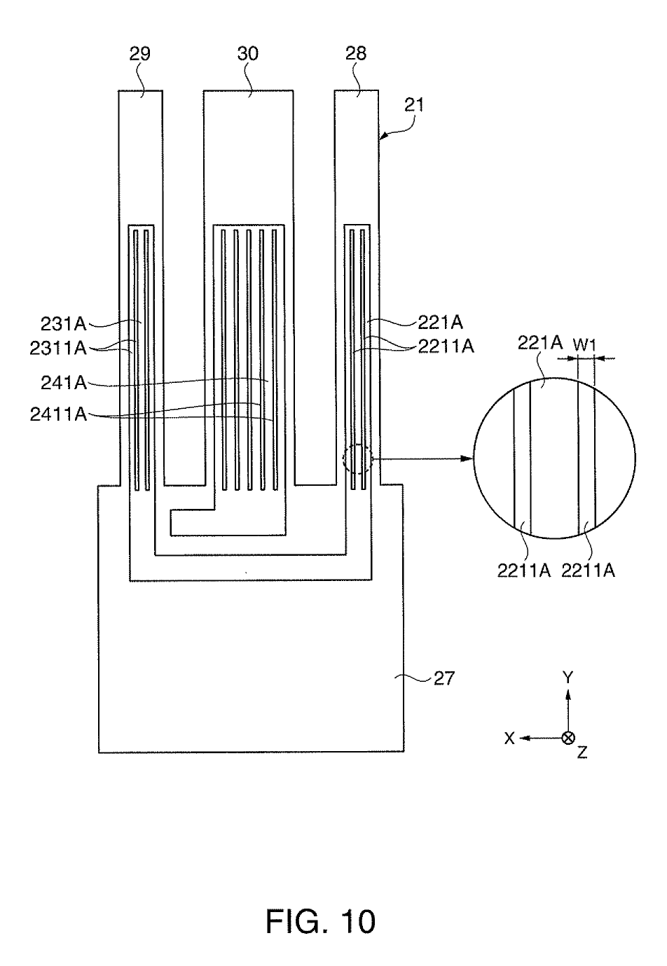

FIG. 9 is a bottom plan view illustrating the resonator body that is included in the resonator device of a second embodiment according to the invention and FIG. 10 is a drawing illustrating the resonator body shown in FIG. 9, in which each of the second electrode layers and each of the piezoelectric body layers that are included in the resonator body are not shown.

Hereinafter, description will be given regarding the resonator device of the second embodiment focused on differences from the above described embodiment and the same articles thereof will not be described repeatedly.

The resonator device of the second embodiment is substantially the same as that of the first embodiment except a plurality of holes that is formed at the first electrode layer and the second electrode layer of each of the piezoelectric material is different in shape seen in the plan view. Also, in FIGS. 9 and 10, the constituent elements similar to those of the above described embodiment are given similar reference numerals.

As shown in FIG. 9, a resonator body 2A of the resonator device according to the embodiment has piezoelectric body elements 22A, 23A, and 24A that are arranged on the resonator substrate 21.

More specifically, the piezoelectric body element 22A is arranged on the resonating arm 28, the piezoelectric body element 23A is arranged on the resonating arm 29, and the piezoelectric body element 24A is arranged on the resonating arm 30.

The piezoelectric body element 22A has a function that performs a flexural vibration of the resonating arm in the Z-axis direction by expanding and contracting by applying an electric current. The piezoelectric body element 23A has a function that performs a flexural vibration of the resonating arm 29 in Z-axis direction by expanding and contracting by applying an electric current. The piezoelectric body element 24A has a function that performs a flexural vibration of the resonating arm 30 in Z-axis direction by expanding and contracting by applying an electric current.

The piezoelectric body element 22A is constituted such that a first electrode layer 221A, the piezoelectric body layer (piezoelectric film) 222, and a second electrode layer 223A are laminated in this order on the resonating arm 28.

As shown in FIG. 9, a plurality of fine holes 2231A that penetrates the second electrode layer 223A in the thickness direction is formed. As shown in FIG. 10, a plurality of fine holes 2211A that penetrates the first electrode layer 221A in the thickness direction is formed. Such a plurality of holes is formed at the first electrode layer 221A and the second electrode layer 223A respectively so that the vibration characteristic of the piezoelectric body element 22A is adjusted.

Similarly, the piezoelectric body element 23A is constituted such that a first electrode layer 231A, the piezoelectric body layer (piezoelectric film) 232, and a second electrode layer 233A are laminated in this order on the resonating arm 29. Also, the piezoelectric body element 24A is constituted such that a first electrode layer 241A, the piezoelectric body layer (piezoelectric film) 242, and a second electrode layer 243A are laminated in this order on the resonating arm 30.

As shown in FIG. 9, a plurality of fine holes 2331A that penetrates the second electrode layer 233A in the thickness direction is formed in a slit shape. As shown in FIG. 10, a plurality of fine holes 2311A that penetrates the first electrode layer 231A in the thickness direction is formed in a slit shape. Such a plurality of holes is formed at the first electrode layer 231A and the second electrode layer 233A respectively so that the vibration characteristic of the piezoelectric body element 23A is adjusted.

As shown in FIG. 9, a plurality of fine holes 2431A that penetrates the second electrode layer 243A in the thickness direction is formed in a slit shape. As shown in FIG. 10, a plurality of fine holes 2411A that penetrates the first electrode layer 241A in the thickness direction is formed in a slit shape. Such a plurality of holes is formed at the first electrode layer 241A and the second electrode layer 243A respectively so that the vibration characteristic of the piezoelectric body element 24A is adjusted.

The adjustment of the vibration characteristic of the piezoelectric body element 22A will be described. The adjustment of the vibration characteristic of the piezoelectric body elements 23A and 24A is the same as that of the piezoelectric body element 22A so that the description thereof is omitted.

As described above, a plurality of fine holes 2211A that penetrates the first electrode layer 221A in the thickness direction is formed and a plurality of fine holes 2231A that penetrates the second electrode layer 223A in the thickness direction is formed at the piezoelectric body element 22A.

Specifically, each of the holes 2211A and 2231A is a slit shape seen from the plan view. The shape of the holes 2211A and 2231A when the first electrode layer 221A or the second electrode layer 223A are seen from the plan view can be easily formed with a highly precise dimension and position. The negative influence that is exerted on the piezoelectric body element 22A can also be small. Specifically, the width, the distance of the pitch (the distance), the length, or the like of each of the holes 2211A and 2231A are changed so that the vibration characteristic of the piezoelectric body element 22A can be adjusted. Thus, the piezoelectric body element 22A can be relatively simply adjusted to the desired vibration characteristic.

Each of the holes 2211A and 2231A having the slit shape is extended to the extension direction of the resonating arm 28. Thus, the formation of a plurality of the holes 2211A and 2231A can prevent from negatively influencing to the vibration characteristic of the piezoelectric body element 22A. Thus, the piezoelectric body element 22A can be relatively simply adjusted to the desired vibration characteristic. Each of the holes 2211A and 2231A having the slit shape may also be formed so as to extend to the width direction that is orthogonal to the extension direction of the resonating arm 28 or to be parallel in the extension direction of the resonating arm 28 having a predetermined tilt.

Also, a plurality of the holes 2211A and a plurality of holes 2231A are formed so as to have the same pitch to each other. Thus, even in the point, the formation of a plurality of the holes 2211A and 2231A can prevent negatively influencing the vibration characteristic of the piezoelectric body element 22A.

A plurality of holes 2211A and a plurality of holes 2231A are formed so as to not overlap each other as seen in the plan view. For example, a plurality of holes 2211A is formed in the same pitch or integer pitch to a plurality of holes 2231A and formed half a pitch shifted seen in the plan view to a plurality of holes 2231A. Thus, the change of the vibration characteristic can be increased by the formation of the holes 2211A and the holes 2231A of the piezoelectric body element 22A. Also, the holes 2211A and the holes 2231A may be formed in different pitches to each other.

The average widths W1 and W3 of the plurality of holes 2211A and 2231A having the slit shape are preferably 0.01 to 100 μm and more preferably 0.1 to 10 μm respectively. Thus, the formation of the plurality of holes 2211A and 2231A is relatively easily performed and the piezoelectric body element 22A can be adjusted to a desired vibration characteristic.

Meanwhile, if the average diameters W1 and W3 are less than the lower limit, the formation of a plurality of the holes 2211A and 2231A may be difficult by constitutional constituent material or thickness of the first electrode layer 221A and the second electrode layer 223A. Meanwhile, if the average diameters W1 and W3 are more than the upper limit, the driving force that is generated by the piezoelectric body element 22 generates unevenness and negative influence may be exerted to the vibration characteristic of the resonating arm 28 by the range or the position in which the piezoelectric body element 22A is formed.

The average width W1 of a plurality of holes 2211A and the average width W3 of a plurality of holes 2231A may be different to each other, however it is preferable that they are similar to each other. Thus, the vibration characteristic of the piezoelectric body element 22A can be easily adjusted.

According to the above-described second embodiment, the same effect as that of the first embodiment can be present.

### Third Embodiment

Next, the third embodiment of the resonator device according to the invention will be described.

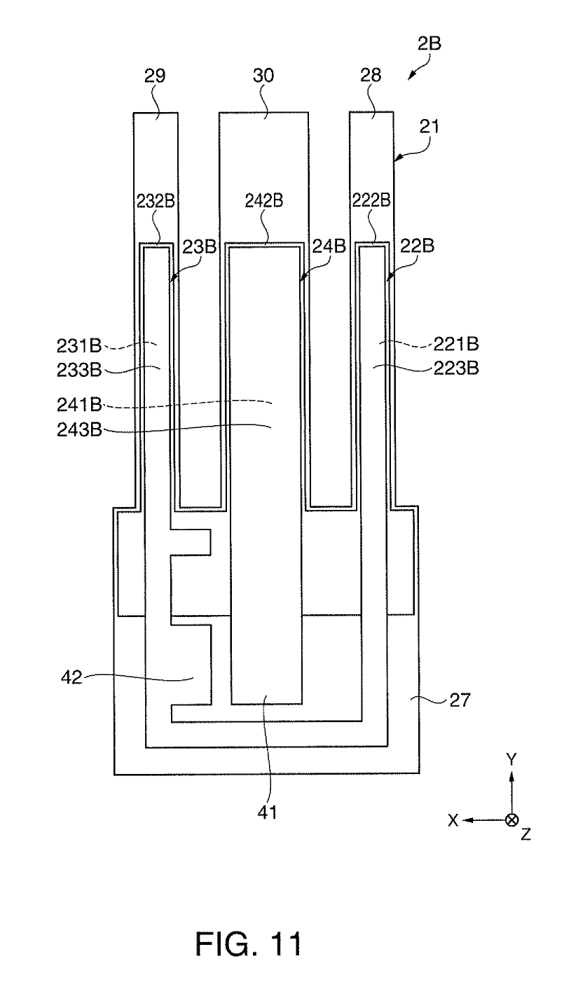

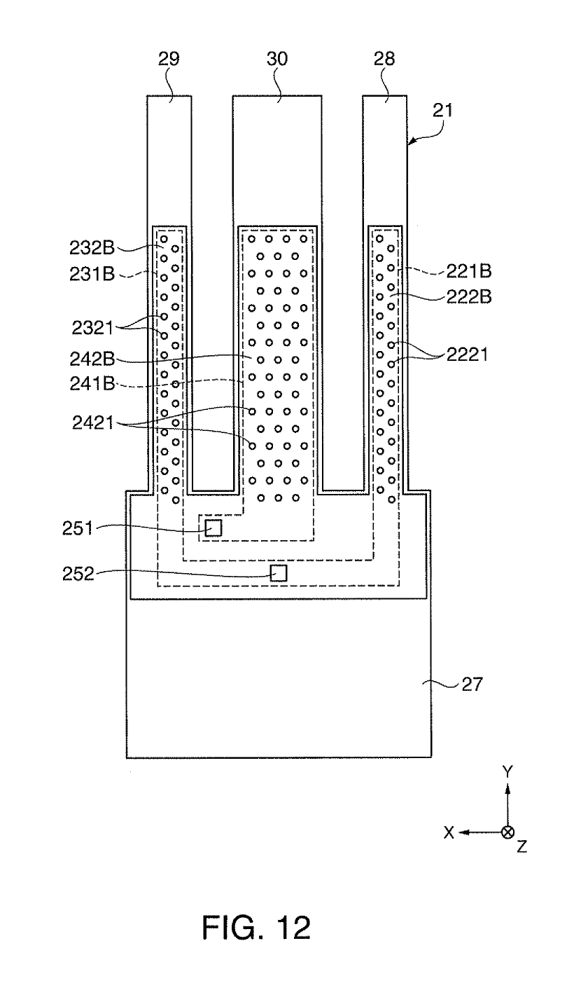

FIG. 11 is a bottom plan view illustrating the resonator body that is included in the resonator device of a third embodiment according to the invention and FIG. 12 is a drawing illustrating the resonator body shown in FIG. 11, in which the second electrode layers that are included in the resonator body are not shown.

Hereinafter, description will be given regarding the resonator device of the third embodiment focused on differences from the above described embodiments and the same articles thereof will not be described repeatedly.

The resonator device of the third embodiment is substantially the same as that of the first embodiment except a plurality of fine holes of the first electrode layer and the second electrode layer of each of the piezoelectric body elements is omitted and a plurality of fine holes is formed at the piezoelectric body layer of each of the piezoelectric body elements. Also, in FIGS. 11 and 12, the constituent elements similar to those of above described embodiment are given similar reference numerals.

As shown in FIG. 11, the resonator body 2B of the resonator device according to the embodiment has the piezoelectric body elements 22B, 23B and 24B that are arranged on the resonator substrate 21.

Further specifically, the piezoelectric body element 22B is arranged on the resonating arm 28, the piezoelectric body element 23B is arranged on the resonating arm 29 and the piezoelectric body element 24B is arranged on the resonating arm 30.

The piezoelectric body element 223 has a function that performs a flexural vibration of the resonating arm in the Z-axis direction by expanding and contracting by applying an electric current. The piezoelectric body element 23B has a function that performs a flexural vibration of the resonating arm 29 in Z-axis direction by expanding and contracting by applying an electric current. The piezoelectric body element 24B has a function that performs a flexural vibration of the resonating arm 30 in Z-axis direction by expanding and contracting by applying an electric current.

The piezoelectric body element 22B is constituted such that a first electrode layer 221B, a piezoelectric body layer (piezoelectric film) 222B and a second electrode layer 223B are laminated in this order on the resonating arm 28.

As shown in FIG. 12, a plurality of fine holes 2221 that penetrates the piezoelectric body layer 222B in the thickness direction is formed. Such a plurality of holes is formed at the piezoelectric body layer 222B so that the vibration characteristic of the piezoelectric body element 22B is adjusted.

Similarly, the piezoelectric body element 23B is constituted such that a first electrode layer 231B, a piezoelectric body layer (piezoelectric film) 232B and a second electrode layer 233B are laminated in this order on the resonating arm 29. Also, the piezoelectric body element 24B is constituted such that a first electrode layer 241B, a piezoelectric body layer (piezoelectric film) 242B and a second electrode layer 243B are laminated in this order on the resonating arm 30.

As shown in FIG. 12, a plurality of fine holes 2321 that penetrates the piezoelectric body layer 232B in the thickness direction is formed. Such a plurality of holes is formed at the piezoelectric body layer 232B so that the vibration characteristic of the piezoelectric body element 23B is adjusted.

Also shown in FIG. 12, a plurality of fine holes 2421 that penetrates the piezoelectric body layer 242B in the thickness direction is formed. Such a plurality of holes is formed at the piezoelectric body layer 242B so that the vibration characteristic of the piezoelectric body element 24B is adjusted.

The adjustment of the vibration characteristic of the piezoelectric body element 22B will be described. The adjustment of the vibration characteristic of the piezoelectric body elements 23B and 24B is the same as that of the piezoelectric body element 22B so that the description thereof is omitted.

As described above, a plurality of fine holes 2221 that penetrates the piezoelectric body layer 222B in the thickness direction is formed at the piezoelectric body element 22B. Thus, the effective area of the first electrode layer 221B and the second electrode layer 223B is reduced and then the vibration characteristic of the piezoelectric body element 223 can be adjusted without changing the formation region (driving region) of the piezoelectric body element 22B on the resonating arm 28.

A plurality of holes 2221 is evenly dispersed in the surface direction of the piezoelectric body layer 222B. In other words, a plurality of holes 2221 is formed so as to penetrate the piezoelectric body layer 222B in the thickness direction and evenly dispersed in the surface direction that is substantially orthogonal to the thickness direction. Thus, the piezoelectric body element 22 can be relatively simply adjusted to the desired vibration characteristic. A plurality of holes 2221 may be formed within a region that exerts the driving of the resonating arm 28 out of the piezoelectric body layer 222B and may be partially (for example, a portion of the Y-axis direction) unevenly distributed in the surface, direction of the piezoelectric body layer 222B so as to be dispersed. A plurality of holes 2221 may be dispersed for example, in regular such as matrix shape and may be dispersed in random.

Each of the holes 2221 has a circular shape or substantially circular shape when the piezoelectric body layer 222B is seeing in the plan view. The holes 2221 having the shape seen in plan view can be simply formed in high precise dimension and the negative influence that exerts on the piezoelectric body element 22B can be also decreased. Thus, the piezoelectric body element 223 can be relatively easily adjusted to the desired vibration characteristic.

Each shape of the holes 2221 seen in plan view is not limited to the circular shape or substantially circular shape and for example, may be oval shape, polygon such as triangle and quadrangle or slit shape.

Average diameter of a plurality of the holes 2221 is preferably 0.01 to 100 μm and more preferably 0.1 to 10 μm respectively. Thus, the formation of a plurality of the holes 2221 is relatively easily performed and the piezoelectric body element 22B can be adjusted to the desired vibration characteristic.

When the piezoelectric body layer 222B is seen in the plan view, the ratio (the share of the area) of the area in which a plurality of the holes 2221 takes a share with respect to the entire piezoelectric body layer 222B is determined according to the obtained vibration characteristic of the piezoelectric body element 22. The ratio is preferably 0.1 to 0.8 and more preferably 0.2 to 0.7. Thus, the driving force of the piezoelectric body element 22B is properly maintained while the piezoelectric body element 22B can be adjusted to the desired vibration characteristic.

According to the above described third embodiment, effect of the same as that of the first embodiment can be present.

### Fourth Embodiment

Hereinafter, description will be given regarding a piezoelectric oscillator as the resonator device of the fourth embodiment focused on differences from the above described embodiments and the same articles thereof will not be described repeatedly.

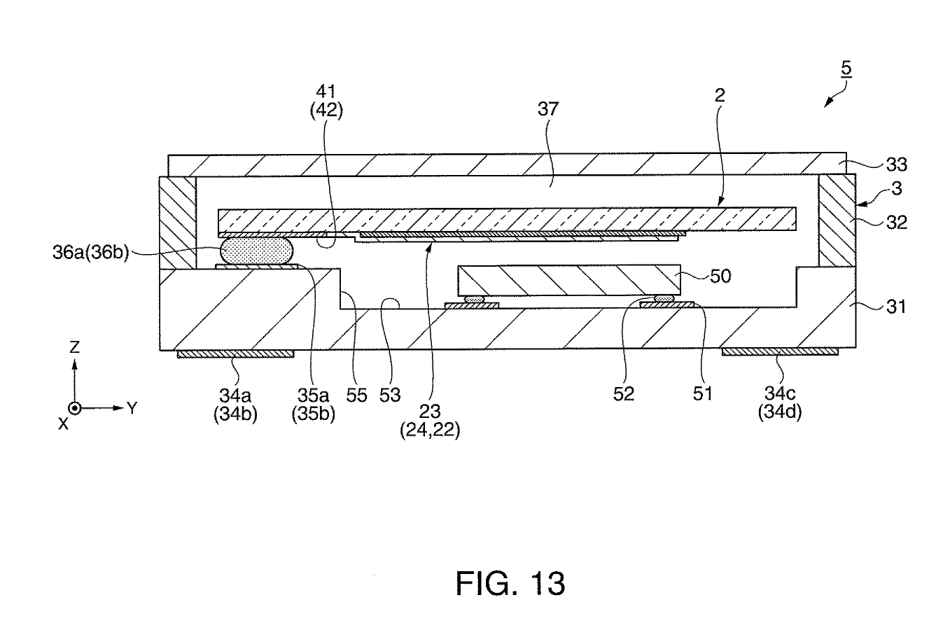

FIG. 13 is a cross section view illustrating the piezoelectric oscillator as the resonator device of the fourth embodiment according to the invention. The X-axis, the Y-axis and the Z-axis are illustrated and they are used the same as those of the above-described embodiments.

Hereinafter, each of the constitutions of the piezoelectric oscillator 5 as the resonator device is described with reference to FIG. 13. The constituent elements of the piezoelectric oscillator 5 that are similar to those of the above described embodiment are given similar reference numerals and the description thereof is omitted.

The piezoelectric oscillator 5 has the resonator body 2 that has been described in the above-described embodiments, a semiconductor element 50 as a driving circuit portion having a function that is electrically connected to the resonator body 2 drives at least the resonator body 2; and the package 3 that accommodates the resonator body 2 and the semiconductor element 50.

### Resonator Body

The resonator body 2 is similar to that of the first embodiment so that the description thereof is omitted. In the embodiment, the resonator body 2 is described as a representative example, however, the resonator body 2A or the resonator body 2B may be used.

### Package

Next, description will be given regarding the package 3 that receives and fixes the resonator body 2 and the semiconductor element 50.

As shown in FIG. 13, the package 3 has a plate shaped base substrate 31 on which the concave portion 55 is formed, a frame shaped frame member 32, and a plate shaped lid member 33. The base substrate 31, the frame member 32 and the lid member 33 are laminated in this order from the lower side to the upper side. The base substrate 31 and the frame member 32 are formed by a ceramic material as described below, wired integrally to each other and then connected together. The frame member 32 and the lid member 33 are connected to each other by an adhesive or brazing filler material. Thus, the package 3 accommodates the resonator body 2 and the semiconductor element 50 in an inner space 37 partitioned by the base substrate 31, the frame member 32, and the lid member 33. Electronic components or the like that relate the driving of the resonator body 2 may also be accommodated within the package 3 besides the resonator body 2 and the semiconductor element 50.

As the constituent material of the base substrate 31, it is preferable to have an insulation property (non-conductivity), for example, various types of glass, various types of ceramic material such as oxide ceramics, nitride ceramics, or carbide ceramics, and various types of resin material such as polyimide can be used.

As the constituent material of the frame member 32 and the lid member 33, for example, the same constituent material as the base substrate 31, various types of metal material such as Al or Cu, various types of glass, or the like can be used. Specifically, as the constituent material of the lid member 33, if a material that has light transmittance such as a glass material is used, when a metal coating portion (not shown) is formed at the resonator body 2 beforehand, even though after the resonator body 2 is accommodated in the package 3, the laser irradiates the metal coating portion through the lid member 33, the metal coating portion is removed, and then the mass of the resonator body 2 is decreased (by a mass decreasing method) so that the frequency adjustment of the resonator body 2 can be performed.

A pair of mount electrodes 35a and 35b is formed on the upper surface of the base substrate 31 so as to be exposed to the inner space 37. Conductive adhesives 36a and 36b such as epoxy, polyimide, and silicon including conductive particles are coated (covered) on the mount electrodes 35a and 35b respectively. The resonator body is loaded on the conductive adhesives 36a and 36b. Thus, the resonator body 2 (the base portion 27) is reliably fixed to the mount electrodes 35a and 35b (the base substrate 31).

The fixing is performed with the resonator body 2 being loaded on the conductive 42 adhesives 36a and 36b so that the conductive adhesive 36a is contacted to the connection electrode 42 of the resonator body 2 and the conductive adhesive 36b is contacted to the connection electrode 41 of the resonator body 2. Thus, the resonator body 2 is fixed to the base substrate 31 through the conductive adhesives 36a and 36b. The connection electrode 42 and the mount electrode 35a are electrically connected through the conductive adhesive 36a and the connection electrode 41 and the mount electrode 35b are electrically connected through the conductive adhesive 36b.

The concave portion 55 having a concave bottom surface 53 around which a wall surface is formed is arranged at the base substrate 31. A plurality of lead electrodes 51 is formed at the concave bottom surface 53. A semiconductor element 50 is connected to a plurality of the lead electrodes 51 through the metal bump 52. The semiconductor element 50 and the lead electrode 51 may also be electrically connected through a metal wire (bonding wire) that is formed by, for example, a wire bonding technique.

The lead electrode 51 and the mount electrodes 35a and 35b are electrically connected with a circuit wiring (not shown).

Four outer terminals 34a, 34b, 34c, and 34d are arranged at the lower surface of the base substrate 31.

The outer terminals 34a and 34b out of these four outer terminals 34a to 34d are hot terminals that are electrically connected to the circuit wiring mount electrodes 35a and 35b through a conductive post (not shown) that is arranged at the through hole that is formed in the base substrate 31 respectively. The other two outer terminals 34c and 34d of the outer terminals 34a to 34d may be dummy terminals for increasing the connection strength and uniformizing the distance between the package 3 and the mounting substrate respectively when the package 3 is mounted on the mounting substrate.

As described above, the mount electrodes 35a and 35b, the lead electrode 51 and the outer terminals 34a to 34d can be formed, for example, with gold coating at the base layer of tungsten and nickel coating respectively.

The mount electrodes 35a and 35b and the connection electrodes 41 and 42 may be electrically connected through a metal wire (bonding wire) formed, for example, by a wire bonding technique. In this case, the resonator body 2 can be fixed to the base substrate 31 through an adhesive that does not have conductivity, instead of the conductive adhesives 36a and 36b. Also, if necessary, a writing terminal that is to perform a rewrite (adjustment) of a characteristic inspection of the electronic components or various types of information (for example, the temperature compensating information of the resonator device) within the electronic components may be formed on the lower surface of the base substrate 31, if it is required in a case where the electronic device is accommodated within the package 3.

According to the piezoelectric oscillator 5 of the embodiment, the vibration bodies 2, 2A, and 2B that are used can obtain the desired vibration characteristic relatively simple and at low cost. The piezoelectric oscillator 5 further includes the semiconductor element 50 that is electrically connected to the vibration bodies 2, 2A, and 2B, so that the resonator body can be a more compact size and furthermore the desired vibration characteristic can be obtained relatively simple and at low cost.

The resonator device of each of the above-described embodiments can be applied to various types of electronic devices and the obtained electronic device is become a compact size and has high reliability.

### Electronic Device

The crystal vibration piece of each of the above-described embodiments can be applied to various types of electronic devices and the obtained electronic device has high reliability. Any one of the vibrator and the oscillator that are described in the above embodiments can be used in the electronic device. If the vibrator is used, a driving circuit portion (not shown) that is electrically connected to the resonator body is arranged.

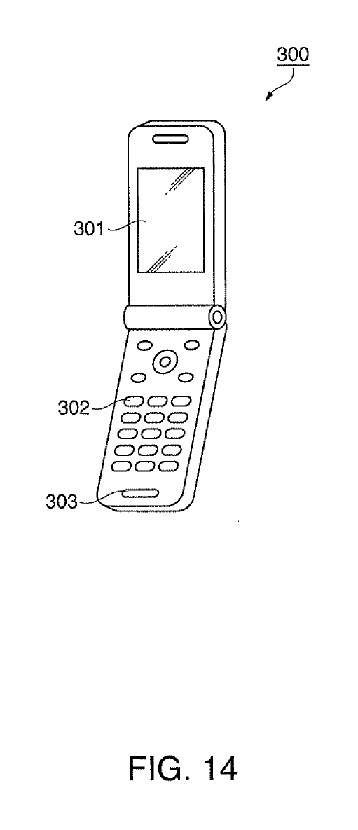

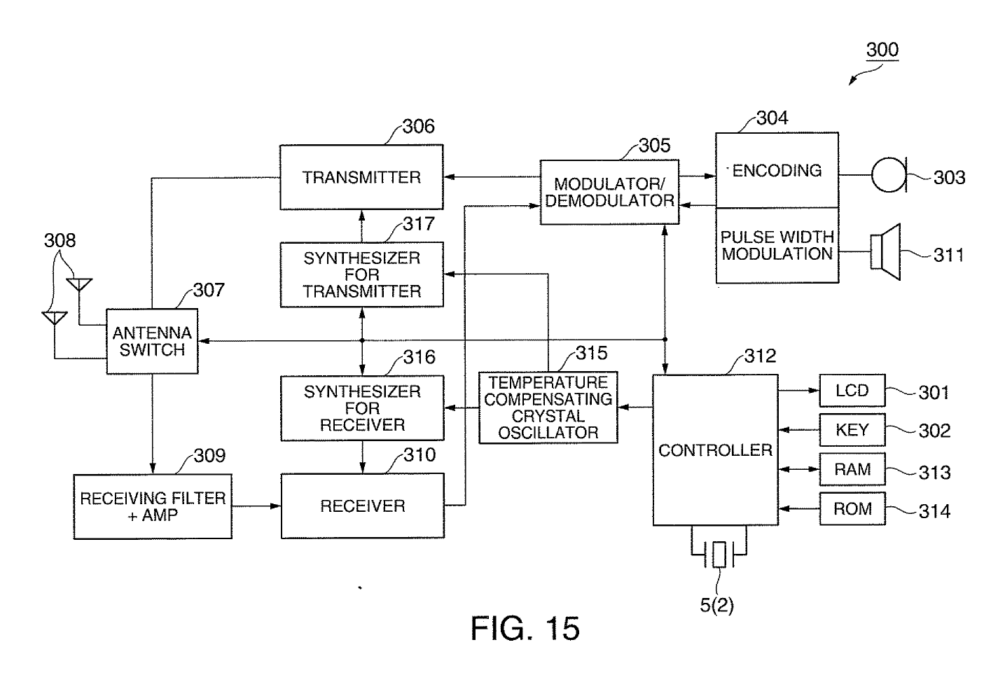

FIGS. 14 and 15 illustrate a cellular phone as an example of the electronic device according to the invention. FIG. 14 is a perspective view schematically illustrating the outer shape of the cellular phone and FIG. 15 is a circuit block diagram illustrating a circuit portion of the cellular phone.

The cellular phone 300 can use the above-described resonator body 2 or the piezoelectric oscillator 5. In this embodiment, an example which uses the resonator body is described. The constitution and operation of the resonator body 2 are given similar reference numerals and the description thereof is omitted.

As shown in FIG. 14, the cellular phone 300 includes an LCD (Liquid Crystal Display) 301 that is a display portion, a key 302 that is an input portion such as numbers, a microphone 303, a speaker 311, a circuit portion (not shown), and the like.

As shown in FIG. 15, in a case where transmittance is performed in the cellular phone 300, when the user inputs a voice of themselves to the microphone 303, a signal is transmitted from an start antenna 308 via a pulse width modulation-encoding block 304 and a modulator/demodulator block 305 and through a transmitter 306 and an antenna switch 307.

Meanwhile, a signal that is received from a telephone of other person is received from the antenna 308 and input to the modulator/demodulator block 305 from a receiver 310 via the antenna switch 307 and a receiving filter 309. Thus, the modulated or demodulated signal is output to a speaker 311 as a voice via the pulse width modulation-encoding block 304.

A controller 312 is arranged to control the antenna switch 307, the modulator/demodulator block 305 or the like.

The controller 312 is required to be high precise so as to also control the LCD 301 that is other than the above-described display portion, or a key 302 that is the input portion of the numbers or the like, what is more a RAM 313 or a ROM 314. There is also a require to for the cellular phone 300 to be compact.

The above described resonator body 2 is used to meet the need.

The cellular phone 300 also includes a temperature compensating crystal oscillator 315, a synthesizer 316 for the receiver, a synthesizer 317 for the transmitter, or the like as other constitution blocks, however, the description thereof is omitted.

The vibration bodies 2, 2A, and 2B that are used in the cellular phone 300 and the vibration bodies 2, 2A, and 2B of the vibration oscillator 5 can obtain the desired vibration characteristic relatively easily and at low cost as described above. Also, the vibration oscillator 5 includes the semiconductor element 50 that is electrically connected to the vibration bodies 2, 2A, and 2B so that compact size thereof can be obtained and the desired vibration characteristic can be obtained more relatively easily and at low cost.

Accordingly, the electronic device (the cellular phone 300) that uses the resonator body 2 or the vibration oscillator 5 can maintain the stable characteristic and a still lower cost and compact size can be accomplished.

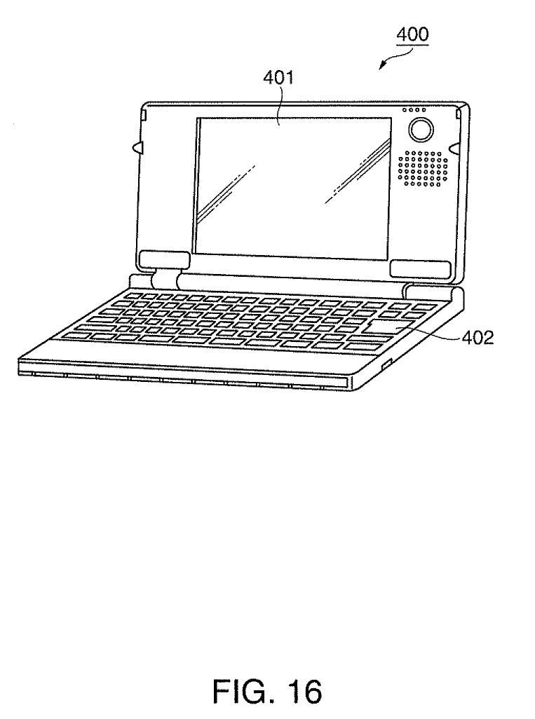

As the electronic device including the resonator body 2 according to the invention, there is a personal computer (a mobile personal computer) 400 as shown in FIG. 16. The personal computer 400 includes a display portion 401, an input key portion 402, or the like, and uses the above described resonator body 2 as the reference clock of the electric control.

The electronic devices including the crystal vibration piece according to the invention, besides the above-described examples, includes, for example, digital-still cameras, ink jet ejection apparatuses (for example, ink jet printers), laptop personal computers, televisions, video cameras, video tape recorders, car navigation apparatuses, pagers, electronic pocket books (including communication functions), electronic dictionaries, calculators, electronic gaming machines, word processors, work stations, television phones, surveillance TV monitors, electronic binoculars, POS terminals, medical devices (for example, electronic thermometers, sphygmomanometers, glucose meters, electrocardiogram measuring systems, ultrasonic diagnosis devices, and electronic endoscopes), fishfinders, various measurement instruments, various indicators (for example, indicators used in vehicles, airplanes, and ships), flight simulators, and the like.

While the resonator body and resonator device according to the invention has been described based on the embodiment illustrated in the drawings, the invention is not limited to the embodiments; the configuration of the respective portions can be replaced with any configurations having the same function. Moreover, other arbitrary constituent elements may be added to the invention. The invention may combine two or more arbitrary constituents (characteristics) of each of the embodiments.

For example, in the above described embodiments, the description has been given in a case where the resonator body has three vibration arms, however, the number of vibration arms may be one, two, or four or more.

Furthermore, in the above described first and second embodiments, the description has been given in a case where a plurality of fine holes is formed at both of the first electrode layer and the second electrode layer of the piezoelectric body elements, however, even though a plurality of fine holes is formed at only one electrode layer in any one of the first electrode layer or the second electrode layer, the vibration characteristic of the piezoelectric body element can be adjusted.

Also, the resonator device of the invention may be applied to a gyro sensor or the like, in addition to piezoelectric oscillators such as a crystal oscillator (SPXO), a voltage-controlled crystal oscillator (VCXO), a temperature-compensated crystal oscillator (TOXO), or an oven-controlled crystal oscillator (OCXO).

The entire disclosure of Japanese Patent Application Nos: 2010-062059, filed Mar. 18, 2010 and 2010-292041, filed Dec. 28, 2010 are expressly incorporated by reference herein.

What is claimed is:

1. A resonator body comprising:
a base portion,
resonating arms that are extended from the base portion and
piezoelectric body elements that are arranged on the resonating arms and vibrate the resonating arms by expanding and contracting by applying an electric current,
wherein the piezoelectric body elements include a first electrode layer, a second electrode layer, and a piezoelectric body layer that is positioned between the first electrode layer and the second electrode layer, and
wherein a plurality of holes that penetrates at least one layer of the first electrode layer, the piezoelectric body layer, and the second electrode layer in a thickness direction is formed.

2. The resonator body according to claim 1, wherein the plurality of holes is formed on at least one side of the first electrode layer and the second electrode layer.

3. The resonator body according to claim 2, wherein the plurality of holes is formed at least on the first electrode layer.

4. The resonator body according to claim 3, wherein the plurality of holes is formed on both of the first electrode layer and the second electrode layer.

5. The resonator body according to claim 2, wherein the plurality of holes is not formed on the piezoelectric body layer.

6. The resonator body according to claim 1, wherein the plurality of holes is formed on the piezoelectric body layer.

7. The resonator body according to claim 1, wherein a plurality of holes is evenly dispersed in a surface direction of the layer.

8. The resonator body according to claim 1, wherein each of the holes is a circular shape when the layer is seen in a plan view.

9. The resonator body according to claim 8, wherein an average diameter of a plurality of the holes is 0.01 to 100 μm.

10. The resonator body according to claim 1, wherein each of the holes is a slit shape when the layer is seen in a plan view.

11. The resonator body according to claim 10, wherein each hole having the slit shape is extended to an extension direction of the resonating arm or to a width direction that is orthogonal to the extension direction of the resonating arm.

12. The resonator body according to claim 11, wherein an average width of a plurality of holes having the slit shape is 0.01 to 100 μm.

13. The resonator body according to claim 1, wherein a ratio of the area in which the plurality of holes takes a share with respect to the entire layer is 0.1 to 0.8 when the layer is seen in a plan view.

14. A resonator device comprising:
the resonator body according to claim 1, and
a package that accommodates the resonator body.

15. A resonator device comprising:
the resonator body according to claim 1,
a driving circuit portion that is electrically connected to the resonator body, and
a package that accommodates the resonator body and the driving circuit portion.

16. An electronic device comprising:
the resonator device according to claim 1.
